(19) United States
(12) Patent Application Publication
(10) Pub. No.: US 2014/0300423 A1
(43) Pub. Date: Oct. 9, 2014

(54) CLOCK GENERATING CIRCUIT HAVING PARASITIC OSCILLATION SUPPRESSING UNIT AND METHOD OF SUPPRESSING PARASITIC OSCILLATION USING THE SAME

(71) Applicant: Samsung Electro-mechanics Co., Ltd., Suwon (KR)

(72) Inventor: Yo Sub MOON, Osan (KR)

(73) Assignee: Samsung Electro-mechanics Co., Ltd., Suwon (KR)

(21) Appl. No.: 14/048,950

(22) Filed: Oct. 8, 2013

(30) Foreign Application Priority Data
Apr. 5, 2013 (KR) 10-2013-0037443

(51) Int. Cl. H03B 1/04

(52) U.S. Cl. CPC H03B 1/04
USPC 331/105

(57) ABSTRACT

Disclosed herein are a clock generating circuit having a parasitic oscillation suppressing unit and a method of suppressing parasitic oscillation using the same. An output VDD of a parasitic component eliminating circuit is maintained in a high or low state according to the condition in which the output VDD falls from the high state to the low state and the condition in which the output VDD rises from the low state to the high state based on a threshold voltage VSPH when an input signal of the parasitic component eliminating circuit is changed from 0 to 1 and a threshold voltage VSPL when the input signal of the parasitic component eliminating circuit is changed from 1 to 0. Undesired parasitic oscillation is eliminated (suppressed) by the parasitic component eliminating circuit provided between a oscillator and a buffer.

### CROSS REFERENCE(S) TO RELATED APPLICATIONS

This application claims the benefit under 35 U.S.C. Section 119 of Korean Patent Application Serial No. 10-2013-0037443, entitled “Clock Generating Circuit Having Parasitic Oscillation Suppressing Unit and Method of Suppressing Parasitic Oscillation Using the Same” filed on Apr. 5, 2013, which is hereby incorporated by reference in its entirety into this application.

### BACKGROUND OF THE INVENTION

1. Technical Field

The present invention relates to a clock generating circuit, and more particularly, to a clock generating circuit having a parasitic oscillation suppressing unit capable of minimizing a malfunction due to an external influence, and a method of suppressing parasitic oscillation using the same.

2. Description of the Related Art

Most of the integrated circuits (ICs) have used a comparatively accurate crystal oscillator in order to use a system clock or design a frequency synthesizer, or the like.

Particularly, in a real time clock (RTC), an oscillator using a crystal resonator is necessary in order to represent an accurate time. In addition, in order to generate an accurate clock having a desired frequency, an influence of noise or a signal introduced from the outside should be minimized.

FIG. 1 is a diagram showing a configuration of a clock generating circuit according to the related art.

Referring to FIG. 1, the clock generating circuit 100 according to the related art is configured to include an oscillator 101 oscillating a sine wave having a predetermined frequency, a first buffer 102 receiving the sine wave output from the oscillator 101 and outputting a square wave represented by 0 and 1, a second buffer 103 receiving an output of the first buffer 102 and outputting an opposite value to the received value, and a crystal resonator 104 resonated in a desired specific frequency band in order to represent an accurate time. Here, particularly, an output of the oscillator 101 is fed back as an input of the oscillator 101 through the crystal resonator 104 to thereby be oscillated. As shown in FIG. 1, the oscillator 101 is configured in an inverter form, and the first and second buffers 102 and 103 are also configured of an inverter chain.

In the clock generating circuit 100 according to the related art having the above-mentioned configuration, since the oscillator 101 for RTC having a relatively low frequency is oscillated at a frequency of 32.768 KHz, a rising time period in which inputs of the first and second buffers 102 and 103 are transited from 0 to 1 and a falling time period in which the inputs of the first and second buffers 102 and 103 are transited from 1 to 0 are long. In addition, since all transistors are operated as amplifiers in these sections, even though a small signal is introduced from the outside, a clock malfunctions.

That is, as shown in FIG. 2, in the case in which an undesired parasitic component is introduced between the oscillator 101 and the first buffer 102, parasitic oscillator occurs in a period in which a square wave output pulse of the first buffer 102 is transited from 0 to 1 and from 1 to 0. Finally, a plurality of clocks are generated in the above-mentioned period in a clock output terminal Clock out of the second buffer 103, such that a malfunction of the clock occurs.

As a method of suppressing the parasitic oscillator as described above, there is a method of suppressing the parasitic oscillator using a buffer having a large size in order to decrease rising and falling times of the pulse. However, in this method, a large current is consumed, and it is impossible to prevent parasitic components in the case in which the parasitic components are generated in the oscillator and the buffer. In addition, there is a method of suppressing the parasitic oscillator by installing a bypass capacitor at the outside. However, in this method, additional external pins are required.

### RELATED ART DOCUMENT

### Patent Document

(Patent Document 1) Korean Patent Laid-Open Publication No. 10-1999-0014691

(Patent Document 2) Japanese Patent Laid-Open Publication No. 1993-121939

### SUMMARY OF THE INVENTION

An object of the present invention is to provide a clock generating circuit having a parasitic oscillation suppressing unit capable of minimizing a malfunction due to an external influence by adding a circuit eliminating (suppressing) parasitic oscillation between an oscillator and a buffer to eliminate undesired parasitic oscillation, and a method of suppressing parasitic oscillation using the same.

According to an exemplary embodiment of the present invention, there is provided a clock generating circuit having a parasitic oscillation suppressing unit, including: an oscillator receiving a driving signal for oscillation and oscillating a sine wave having a predetermined frequency; a first buffer receiving the sine wave output from the oscillator and outputting a square wave represented by 0 and 1; a second buffer receiving an output from the first buffer and outputting an opposite value to the received value; a crystal resonator connected in parallel with the oscillator, receiving a driving signal from the outside, resonated in a desired specific frequency band so as to generate a clock of an accurate time at a final output terminal, providing an input signal of the oscillator, and receiving an output signal fed back from the oscillator; and a parasitic component eliminating circuit installed between the oscillator and the first buffer in order to eliminate a parasitic component introduced between the oscillator and the first buffer.

The parasitic component eliminating circuit may include: a VSPH setting unit setting a threshold voltage VSPH when an input signal of the parasitic component eliminating circuit is changed from 0 to 1; and a VSPL setting unit setting a threshold voltage VSPL when the input signal of the parasitic component eliminating circuit is changed from 1 to 0.

The VSPH setting unit may be configured of a serial/parallel combination circuit of a plurality of n-channel metal oxide semiconductors (NMOSs).

The VSPH setting unit may include: a first NMOS having a source connected to a ground and a gate connected to a common connection node of an input terminal; a second NMOS having a source connected to a drain of the first NMOS and a gate connected to the common connection node of the input terminal; and a third NMOS having a source connected to a common connection node between the drain of the first NMOS and the second NMOS, a drain connected to a voltage source, and a gate connected to a common connection node of an output terminal.

The VSPH setting unit may set the VSPH by adjusting lengths and widths of the first and third NMOSs.

The VSPL setting unit may be configured of a serial/parallel combination circuit of a plurality of p-channel metal oxide semiconductors (PMOSs).

The VSPL setting unit may include: a first PMOS having a drain connected to the drain of the second NMOS and a gate connected to the common connection node of the input terminal; a second PMOS having a source connected to the voltage source, a drain connected to a source of the first PMOS, and a gate connected to the common connection node of the input terminal; and a third PMOS having a source connected to a common connection node between the source of the first PMOS and the drain of the second PMOS, a drain connected to the ground, and a gate connected to the common connection node of the output terminal.

The VSPL setting unit may set the VSPL by adjusting lengths and widths of the second and third PMOSs.

According to another exemplary embodiment of the present invention, there is provided a method of suppressing parasitic oscillation using a clock generating circuit having a parasitic oscillation suppressing unit and including an oscillator, a first buffer, a second buffer, a crystal resonator, and a parasitic component eliminating circuit, the method including: setting a threshold voltage VSPH when an input signal is changed from 0 to 1 by a VSPH setting unit of the parasitic component eliminating circuit and setting a threshold voltage VSPL when the input signal is changed from 1 to 0 is set by a VSPK setting unit of the parasitic component eliminating circuit; and maintaining an output VDD of the parasitic component eliminating circuit in a high or low state according to the condition in which the output VDD falls from the high state to the low state and the condition in which the output VDD rises from the low state to the high state based on a difference between the VSPH and the VSPL.

The condition in which the output VDD of the parasitic component eliminating circuit falls from the high state to the low state may correspond to the case in which the input signal rises to be higher than the VSPH, and the condition in which the output VDD of the parasitic component eliminating circuit rises from the low state to the high state may correspond to the case in which the input signal falls to be lower than the VSPL.

The VSPH setting unit may include: a first NMOS having a source connected to a ground and a gate connected to a common connection node of an input terminal; a second NMOS having a source connected to a drain of the first NMOS and a gate connected to the common connection node of the input terminal; and a third NMOS having a source connected to a common connection node between the drain of the first NMOS and the second NMOS, a drain connected to a voltage source, and a gate connected to a common connection node of an output terminal.

The VSPH setting unit may set the VSPH by adjusting lengths and widths of the first and third NMOSs.

The VSPL setting unit may include: a first PMOS having a drain connected to the drain of the second NMOS and a gate connected to the common connection node of the input terminal; a second PMOS having a source connected to the voltage source, a drain connected to a source of the first PMOS, and a gate connected to the common connection node of the input terminal; and a third PMOS having a source connected to a common connection node between the source of the first PMOS and the drain of the second PMOS, a drain connected to the ground, and a gate connected to the common connection node of the output terminal.

The VSPL setting unit may set the VSPL by adjusting lengths and widths of the second and third PMOSs.

### BRIEF DESCRIPTION OF THE DRAWINGS

FIG. 1 is a diagram showing a configuration of a clock generating circuit according to the related art;

FIG. 2 is a diagram describing generation of a malfunction in inverters disposed at a rear end of an oscillator in the case in which a parasitic component is introduced into the clock generating circuit of FIG. 1;

FIG. 3 is a diagram showing a configuration of a clock generating circuit using a crystal oscillator according to an exemplary embodiment of the present invention;

FIG. 4 is a diagram schematically showing a configuration of a parasitic component eliminating circuit of the clock generating circuit using a crystal oscillator according to the exemplary embodiment of the present invention;

FIG. 5 is a diagram showing an internal circuit configuration of the parasitic component eliminating circuit of the clock generating circuit using a crystal oscillator according to the exemplary embodiment of the present invention;

FIG. 6 is a diagram showing waveforms of input/output signals of the parasitic component eliminating circuit in the clock generating circuit using a crystal oscillator according to the exemplary embodiment of the present invention; and

FIG. 7 is a diagram showing a simulation result in the case in which a parasitic component is introduced into the clock generating circuit using a crystal oscillator according to the exemplary embodiment of the present invention.

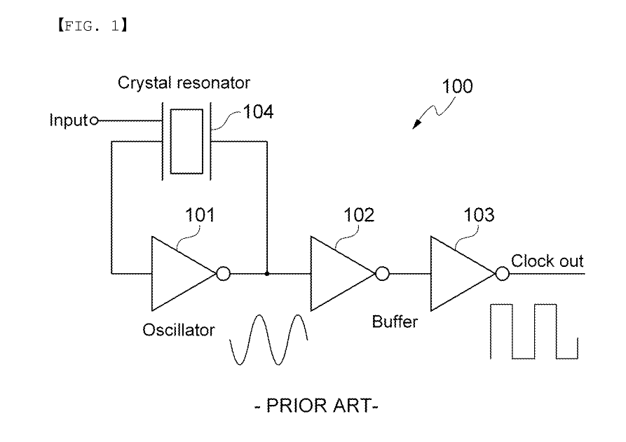

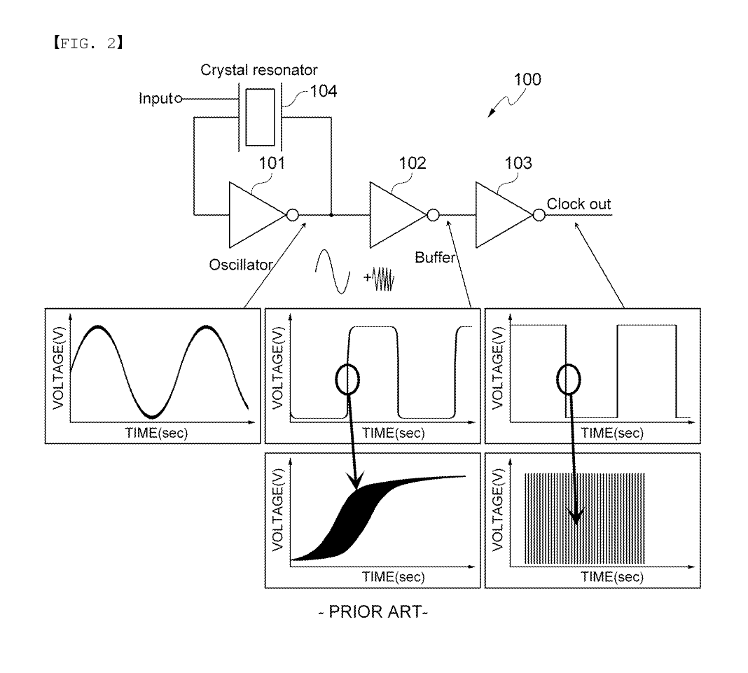

### DESCRIPTION OF THE PREFERRED EMBODIMENTS

Terms and words used in the present specification and claims are not to be construed as a general or dictionary meaning, but are to be construed to meaning and concepts meeting the technical ideas of the present invention based on a principle that the inventors can appropriately define the concepts of terms in order to describe their own inventions in the best mode.

Throughout the present specification, unless explicitly described to the contrary, “comprising” any components will be understood to imply the inclusion of other elements rather than the exclusion of any other elements. A term “part”, “module”, “device”, or the like, described in the specification means a unit of processing at least one function or operation and may be implemented by hardware or software or a combination of hardware and software.

Hereinafter, exemplary embodiments of the present invention will be described in detail with reference to the accompanying drawings.

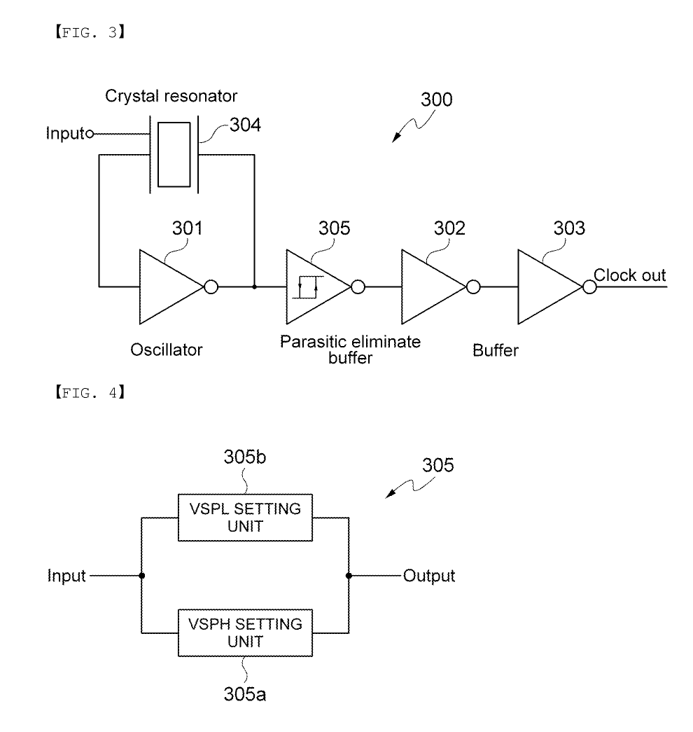

FIG. 3 is a diagram showing a configuration of a clock generating circuit using a crystal oscillator according to an exemplary embodiment of the present invention.

Referring to FIG. 3, the clock generating circuit 300 using a crystal oscillator according to the exemplary embodiment of the present invention is configured to include an oscillator 301, a first buffer 302, a second buffer 303, a crystal resonator 304, and a parasitic component eliminating circuit 305.

The oscillator 301 receives a driving signal for oscillation and oscillates a sine wave having a predetermined frequency.

The first buffer 302 receives the sine wave output from the oscillator 301 and outputs a square wave represented by 0 and 1.

The second buffer 303 receives an output from the first buffer 302 and outputs an opposite value to the received value.

The crystal resonator 304 is connected in parallel with the oscillator 301, receives a driving signal from the outside, is resonated in a desired specific frequency band so as to generate a clock of an accurate time at a final output terminal, provides an input signal of the oscillator 301, and receives an output signal fed back from the oscillator 301.

The parasitic component eliminating circuit 305 is installed between the oscillator 301 and the first buffer 302 and eliminates a parasitic component introduced between the oscillator 301 and the first buffer 302. As described above, the parasitic component is eliminated, such that parasitic oscillator in the oscillator 301 due to the parasitic component introduced between the oscillator 301 and the first buffer 302 is suppressed. Further, as a result, malfunctions at the first and second buffers 302 and 303 disposed at a rear end of the oscillator 301 are prevented.

Here, the parasitic component eliminating circuit 305 may be configured to include a VSPH setting unit 305a setting a threshold voltage VSPH when an input signal of the parasitic component eliminating circuit is changed from 0 to 1 and a VSPL setting unit 305b setting a threshold voltage VSPL when the input signal of the parasitic component eliminating circuit is changed from 1 to 0, as shown in FIG. 4.

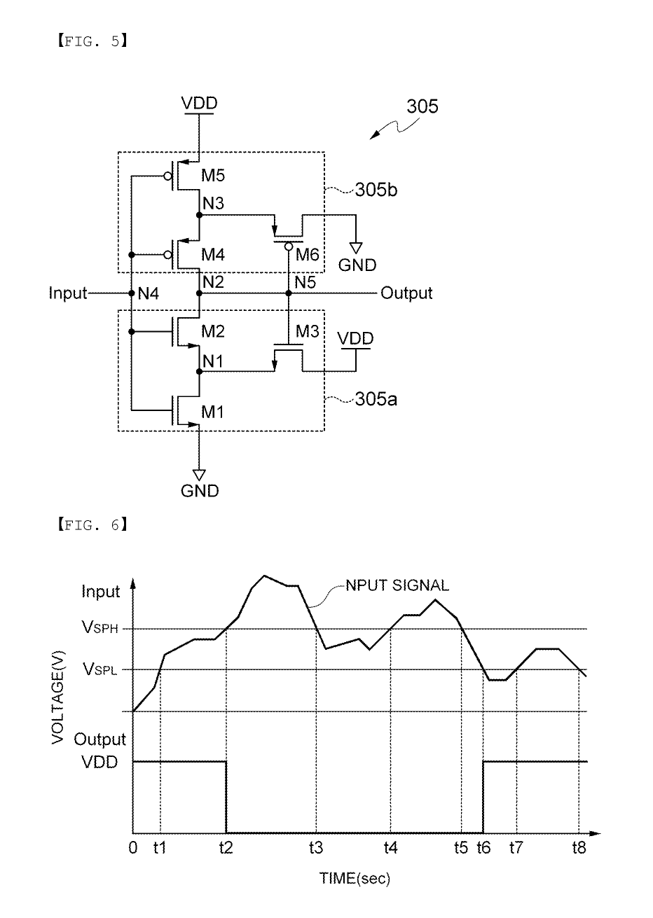

Here, the VSPH setting unit 305a may be configured of a serial/parallel combination circuit of a plurality of n-channel metal oxide semiconductors (NMOSs). That is, as shown in FIG. 5, the VSPH setting unit 305a may be configured to include a first NMOS M1 having a source connected to a ground GND and a gate connected to a common connection node N4 of an input terminal; a second NMOS M2 having a source connected to a drain of the first NMOS M1 and a gate connected to the common connection node N4 of the input terminal; and a third NMOS M3 having a source connected to a common connection node N1 between the drain of the first NMOS M1 and the second NMOS M2, a drain connected to a voltage source VDD, and a gate connected to a common connection node N5 of an output terminal.

In addition, the VSPH setting unit 305a may set the VSPH by adjusting lengths and widths of the first and third NMOSs M1 and M3. This will be described below.

In addition, the VSPL setting unit 305b may be configured of a serial/parallel combination circuit of a plurality of p-channel metal oxide semiconductors (PMOSs). That is, as shown in FIG. 5, the VSPL setting unit 305b may be configured to include a first PMOS M4 having a drain connected to the drain of the second NMOS M2 and a gate connected to the common connection node N4 of the input terminal; a second PMOS M5 having a source connected to the voltage source VDD, a drain connected to a source of the first PMOS M4, and a gate connected to the common connection node N4 of the input terminal; and a third PMOS M6 having a source connected to a common connection node N3 between the source of the first PMOS M4 and the drain of the second PMOS M5, a drain connected to the ground GND, and a gate connected to the common connection node N5 of the output terminal.

In addition, the VSPL setting unit 305b may set the VSPL by adjusting lengths and widths of the second and third PMOSs M5 and M6.

Next, setting of the VSPH and the VSPL will be described in detail.

The VSPH may be represented by the following Equation in connection with the lengths and the widths of the first and third NMOSs M1 and M3 of the VSPH setting unit 305a.

$${k}^{2} = \frac{{W}_{1} {L}_{3}}{{L}_{1} {W}_{3}} = {( \frac{{V}_{DD} - {V}_{SPH}}{{V}_{SPH} - {V}_{THN}} )}^{2} \\ k ( {V}_{SPH} - {V}_{THN} ) = {V}_{DD} - {V}_{SPH} \\ ( k + 1 ) {V}_{SPH} = {V}_{DD} + {kV}_{THN} \\ {V}_{SPH} = \frac{{V}_{DD} + {kV}_{THN}}{k + 1} \qquad [ Equation 1 ]$$

In addition, the VSPL may be represented by the following Equation in connection with the lengths and the widths of the second and third PMOSs M5 and M6 of the VSPL setting unit 305b.

$${l}^{2} = \frac{{W}_{5} {L}_{6}}{{L}_{5} {W}_{6}} = {( \frac{{V}_{SPL}}{{V}_{DD} - {V}_{SPL} - \vert {V}_{THP} \vert} )}^{2} \\ l ( {V}_{DD} - {V}_{SPL} = \vert {V}_{THP} \vert ) = {V}_{SPL} \\ ( l + 1 ) {V}_{SPL} = l ( {V}_{DD} - \vert {V}_{THP} \vert ) \\ {V}_{SPL} = \frac{l ( {V}_{DD} - \vert {V}_{THP} \vert )}{l + 1} \qquad [ Equation 2 ]$$

In the above Equation 1 and Equation 2, k indicates a parameter for calculating VSPH, l indicates a parameter for calculating VSPL, V_{DD} indicates a supply voltage, V_{THN} indicates a threshold voltage of NMOS, V_{THP} indicates a threshold voltage of PMOS, W₁ indicates a width of the first NMOS, L₁ indicates a length of the first NMOS, W₃ indicates a width of the third NMOS, L₃ indicates a length of the third NMOS, W₅ indicates a width of the second PMOS, L₅ indicates a length of the second PMOS, W₆ indicates a width of the third PMOS, and L₆ indicates a length of the third PMOS.

Through the above Equations, the VSPH may be set by adjusting the lengths and the widths of the first and third NMOSs M1 and M3, and the VSPL may be set by the lengths and the width of the second and third PMOSs M5 and M6.

Next, an operation of the parasitic component eliminating circuit and a method of suppressing parasitic oscillation in the clock generating circuit having a crystal oscillator according to the exemplary embodiment of the present invention having the above-mentioned configuration will be described.

In the method of suppressing parasitic oscillation according to the exemplary embodiment of the present invention, which is a method of suppressing parasitic oscillation using the clock generating circuit having a parasitic oscillation suppressing unit and including the oscillator 301, the first buffer 302, the second buffer 303, the crystal resonator 304, and the parasitic component eliminating circuit 305 as described above, first, the threshold voltage VSPH when the input signal is changed from 0 to 1 is set by the VSPH setting unit 305a of the parasitic component eliminating circuit 305, and the threshold voltage VSPL when the input signal is changed from 1 to 0 is set by the VSPK setting unit 305b of the parasitic component eliminating circuit 305.

Then, an output VDD of the parasitic component eliminating circuit 305 is maintained in a high or low state according to the condition in which the output VDD falls from the high state to the low state and the condition in which the output VDD rises from the low state to the high state based on a difference between the VSPH and the VSPL.

Here, the condition in which the output VDD of the parasitic component eliminating circuit 305 falls from the high state to the low state corresponds to the case in which the input signal rises to be higher than the VSPH, and the condition in which the output VDD of the parasitic component eliminating circuit 305 rises from the low state to the high state corresponds to the case in which the input signal falls to be lower than the VSPL.

In addition, the VSPH setting unit 305a may be configured to include the first NMOS M1 having the source connected to the ground GND and the gate connected to the common connection node N4 of the input terminal; the second NMOS M2 having the source connected to the drain of the first NMOS M1 and the gate connected to the common connection node N4 of the input terminal; and the third NMOS M3 having the source connected to the common connection node N1 between the drain of the first NMOS M1 and the second NMOS M2, the drain connected to the voltage source VDD, and the gate connected to the common connection node N5 of the output terminal, as described above.

In addition, the VSPH setting unit 305a may set the VSPH by adjusting the lengths and the widths of the first and third NMOSs M1 and M3.

Further, the VSPL setting unit 305b may be configured to include the first PMOS M4 having the drain connected to the drain of the second NMOS M2 and the gate connected to the common connection node N4 of the input terminal; the second PMOS M5 having the source connected to the voltage source VDD, the drain connected to the source of the first PMOS M4, and the gate connected to the common connection node N4 of the input terminal; and the third PMOS M6 having the source connected to the common connection node N3 between the source of the first PMOS M4 and the drain of the second PMOS M5, the drain connected to the ground GND, and the gate connected to the common connection node N5 of the output terminal, as described above.

In addition, the VSPL setting unit 305b may set the VSPL by adjusting the lengths and the widths of the second and third PMOSs M5 and M6.

Here, since a content in which the VSPH is set by adjusting the lengths and the width of the first and third NMOSs M1 and M3 by the VSPH setting unit 305a and a content in which the VSPL is set by adjusting the lengths and the width of the second and third PMOSs M5 and M6 by the VSPL setting unit 305b have been described above in connection to the above Equation 1 and Equation 2, a description thereof will be omitted.

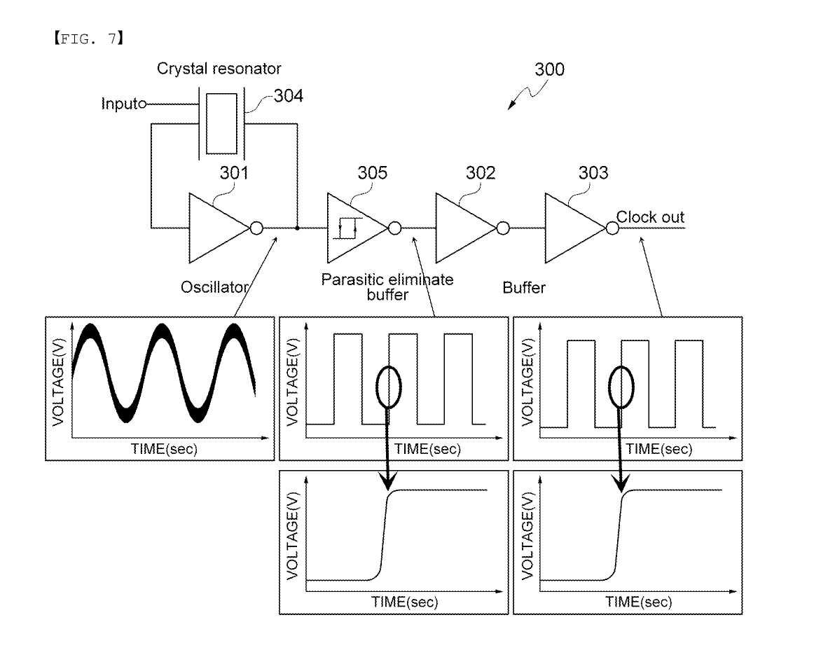

FIG. 6 is a diagram showing waveforms of input/output signals of the parasitic component eliminating circuit in the clock generating circuit using a crystal oscillator according to the exemplary embodiment of the present invention.

As shown in FIG. 6, in the exemplary embodiment of the present invention, a difference is present between the threshold voltage (VSPH) when the input signal of the parasitic component eliminating circuit 305 is changed from 0 to 1 and the threshold voltage VSPL when the input signal of the parasitic component eliminating circuit 305 is changed from 1 to 0, such that the input signal is in a high state when it is a specific value or more and is maintained in the high state before it falls to the specific value or less, thereby preventing a malfunction due to the parasitic oscillation.

In input/output characteristics of the parasitic component eliminating circuit 305 as described above, the output VDD of the parasitic component eliminating circuit 305 falls from the high state to the low state corresponds to the case in which the input signal rises to be higher than the VSPH, and the condition in which the output VDD of the parasitic component eliminating circuit 305 rises from the low state to the high state corresponds to the case in which the input signal falls to be lower than the VSPL. A more detailed description thereof will be provided with reference to FIG. 6.

For example, in a period of 0 to t1 of FIG. 6, the input signal is lower than the VSPL, which corresponds to the condition in which the output VDD rises from the lower state to the high state. Therefore, the output VDD is in the high state. In a period of t1 to t2, the input signal is higher than the VSPL, but is lower than the VSPH, which does not correspond to the condition in which the output VDD falls from the high state to the low state. Therefore, the output VDD is maintained in the high state, which is the previous state.

Meanwhile, in a period of t2 to t3, the input signal is higher than the VSPH, which corresponds to the condition in which the output VDD falls from the high state to the low state. Therefore, the output VDD falls from the high state to the low state, such that the output VDD is in the low state. In a period of t3 to t4, the input signal is lower than the VSPH, but is higher than the VSPL, which does not correspond to the condition in which the output VDD rises from the low state to the high state. Therefore, the output VDD is maintained in the low state, which is the previous state. In a period of t4 to t5, the input signal is higher than the VSPH, which corresponds to the condition in which the output VDD rises from the high state to the low state, such that the output VDD should fall from the high state to the low state. However, since the output VDD is already in the low state, it is maintained in the low state, which is the previous state. Similar to the period of t3 to t4, in a period of t5 to t6, the input signal is lower than the VSPH, but is higher than the VSPL, which does not correspond to the condition in which the output VDD rises from the low state to the high state. Therefore, the output VDD is maintained in the low state, which is the previous state.

In a period of t6 to t7, the input signal is lower than the VSPL, which corresponds to the condition in which the output VDD rises from the low state to the high state. Therefore, the output VDD rises from the low state to the high state, such that the output VDD is in the high state. Similar to the period of t1 to t2, in a period of t7 to t8, the input signal is higher than the VSPL, but is lower than the VSPH, which does not correspond to the condition in which the output VDD falls from the high state to the low state. Therefore, the output VDD is maintained in the high state, which is the previous state.

As described above, since a value changed between the VSPH and the VSPL is continuously maintained as the previous value without having an influence on the circuit, the parasitic oscillation due to the parasitic component may be suppressed.

FIG. 7 is a diagram showing a simulation result in the case in which a parasitic component is introduced into the clock generating circuit using a crystal oscillator according to the exemplary embodiment of the present invention.

As shown in FIG. 7, it may be confirmed that even in the case in which a parasitic component having a predetermined magnitude (for example, up to 300 mV) is introduced from an output terminal of the oscillator 301 or the outside, the parasitic component is eliminated by the parasitic component eliminating circuit 305 (that is, a hysteresis buffer), such that a clock is normally operated. Therefore, an accurate clock may be generated without being affected by a change in an external environment or power.

As described above, the clock generating circuit using a crystal oscillator according to the exemplary embodiment of the present invention includes the parasitic component eliminating circuit added between the oscillator and the buffer, such that undesired parasitic oscillation is eliminated (suppressed) by the parasitic component eliminating circuit even in the case in which the parasitic component is introduced between the oscillator and the buffer, thereby making it possible to minimize a malfunction of a system due to an external influence. As a result, an accurate clock may be generated in spite of the change in the external environment or the power.

As set forth above, according to the exemplary embodiments of the present invention, the parasitic component eliminating circuit is added between the oscillator and the buffer, such that undesired parasitic oscillation is eliminated (suppressed) by the parasitic component eliminating circuit even in the case in which the parasitic component is introduced between the oscillator and the buffer, thereby making it possible to minimize a malfunction of a system due to an external influence. As a result, an accurate clock may be generated in spite of the change in the external environment or the power.

Although the exemplary embodiments of the present invention have been disclosed for illustrative purposes, the present invention is not limited thereto, but those skilled in the art will appreciate that various modifications, additions and substitutions are possible, without departing from the scope and spirit of the invention as disclosed in the accompanying claims. Therefore, the protection scope of the present invention must be analyzed by the appended claims and it should be analyzed that all spirits within a scope equivalent thereto are included in the appended claims of the present invention.

What is claimed is:

1. A clock generating circuit having a parasitic oscillation suppressing unit, comprising:
an oscillator receiving a driving signal for oscillation and oscillating a sine wave having a predetermined frequency;
a first buffer receiving the sine wave output from the oscillator and outputting a square wave represented by 0 and 1;
a second buffer receiving an output from the first buffer and outputting an opposite value to the received value;
a crystal resonator connected in parallel with the oscillator, receiving a driving signal from the outside, resonated in a desired specific frequency band so as to generate a clock of an accurate time at a final output terminal, providing an input signal of the oscillator, and receiving an output signal fed back from the oscillator; and
a parasitic component eliminating circuit installed between the oscillator and the first buffer in order to eliminate a parasitic component introduced between the oscillator and the first buffer.

2. The clock generating circuit according to claim 1, wherein the parasitic component eliminating circuit includes:
a VSPH setting unit setting a threshold voltage VSPH when an input signal of the parasitic component eliminating circuit is changed from 0 to 1; and
a VSPL setting unit setting a threshold voltage VSPL when the input signal of the parasitic component eliminating circuit is changed from 1 to 0.

3. The clock generating circuit according to claim 2, wherein the VSPH setting unit is configured of a serial/parallel combination circuit of a plurality of n-channel metal oxide semiconductors (NMOSs).

4. The clock generating circuit according to claim 3, wherein the VSPH setting unit includes:
a first NMOS having a source connected to a ground and a gate connected to a common connection node of an input terminal;
a second NMOS having a source connected to a drain of the first NMOS and a gate connected to the common connection node of the input terminal; and
a third NMOS having a source connected to a common connection node between the drain of the first NMOS and the second NMOS, a drain connected to a voltage source, and a gate connected to a common connection node of an output terminal.

5. The clock generating circuit according to claim 4, wherein the VSPH setting unit sets the VSPH by adjusting lengths and widths of the first and third NMOSs.

6. The clock generating circuit according to claim 2, wherein the VSPL setting unit is configured of a serial/parallel combination circuit of a plurality of p-channel metal oxide semiconductors (PMOSs).

7. The clock generating circuit according to claim 4, wherein the VSPL setting unit includes:
a first PMOS having a drain connected to the drain of the second NMOS and a gate connected to the common connection node of the input terminal;
a second PMOS having a source connected to the voltage source, a drain connected to a source of the first PMOS, and a gate connected to the common connection node of the input terminal; and
a third PMOS having a source connected to a common connection node between the source of the first PMOS and the drain of the second PMOS, a drain connected to the ground, and a gate connected to the common connection node of the output terminal.

8. The clock generating circuit according to claim 7, wherein the VSPL setting unit sets the VSPL by adjusting lengths and widths of the second and third PMOSs.

9. A method of suppressing parasitic oscillation using a clock generating circuit having a parasitic oscillation suppressing unit and including an oscillator, a first buffer, a second buffer, a crystal resonator, and a parasitic component eliminating circuit, the method comprising:
setting a threshold voltage VSPH when an input signal is changed from 0 to 1 by a VSPH setting unit of the parasitic component eliminating circuit and setting a threshold voltage VSPL when the input signal is changed from 1 to 0 is set by a VSPK setting unit of the parasitic component eliminating circuit; and
maintaining an output VDD of the parasitic component eliminating circuit in a high or low state according to the condition in which the output VDD falls from the high state to the low state and the condition in which the output VDD rises from the low state to the high state based on a difference between the VSPH and the VSPL.

10. The method according to claim 9, wherein the condition in which the output VDD of the parasitic component eliminating circuit falls from the high state to the low state corresponds to the case in which the input signal rises to be higher than the VSPH, and the condition in which the output VDD of the parasitic component eliminating circuit rises from the low state to the high state corresponds to the case in which the input signal falls to be lower than the VSPL.

11. The method according to claim 9, wherein the VSPH setting unit includes:
a first NMOS having a source connected to a ground and a gate connected to a common connection node of an input terminal;
a second NMOS having a source connected to a drain of the first NMOS and a gate connected to the common connection node of the input terminal; and
a third NMOS having a source connected to a common connection node between the drain of the first NMOS and the second NMOS, a drain connected to a voltage source, and a gate connected to a common connection node of an output terminal.

12. The method according to claim 11, wherein the VSPH setting unit sets the VSPH by adjusting lengths and widths of the first and third NMOSs.

13. The method according to claim 11, wherein the VSPL setting unit includes:
a first PMOS having a drain connected to the drain of the second NMOS and a gate connected to the common connection node of the input terminal;
a second PMOS having a source connected to the voltage source, a drain connected to a source of the first PMOS, and a gate connected to the common connection node of the input terminal; and
a third PMOS having a source connected to a common connection node between the source of the first PMOS and the drain of the second PMOS, a drain connected to the ground, and a gate connected to the common connection node of the output terminal.

14. The method according to claim 13, wherein the VSPL setting unit sets the VSPL by adjusting lengths and widths of the second and third PMOSs.
